(19) United States
(12) Patent Application Publication
(10) Pub. No.: US 2016/0109523 A1
(43) Pub. Date: Apr. 21, 2016

(54) APPARATUS AND METHOD FOR CALCULATING STATE OF CHARGE

(71) Applicants: Hyundai Motor Company, Seoul (KR); Kia Motors Corporation, Seoul (KR)

(72) Inventors: Woo Sung Kim, Suwon (KR); Dong Gil Ha, Changwon (KR)

(21) Appl. No.: 14/562,950

(22) Filed: Dec. 8, 2014

(30) Foreign Application Priority Data
Oct. 17, 2014 (KR) 10-2014-0140472

(51) Int. Cl. G01R 31/36

(52) U.S. Cl. CPC G01R 31/3634; G01R 31/3662; G01R 31/3648

(57) ABSTRACT

An apparatus for calculating State of Charge (SOC) of a secondary battery by correcting a terminal voltage includes: a voltage measuring device that measures a terminal voltage of a battery; a voltage corrector that corrects the terminal voltage using a predetermined factor obtained from a characteristic of the battery; and a SOC calculator that calculates SOC of the battery based on the corrected terminal voltage. A method for calculating SOC includes steps of: measuring the terminal voltage of a battery; correcting the terminal voltage using the predetermined factor obtained from the characteristic of the battery; and calculating SOC of the battery based on the corrected terminal voltage.

### CROSS-REFERENCE TO RELATED APPLICATION

This application is based on and claims under 35 U.S.C. §119(a) the benefit of Korean Patent Application No. 10-2014-0140472, filed on Oct. 17, 2014 in the Korean Intellectual Property Office, the disclosure of which is incorporated herein in its entirety by reference.

### BACKGROUND

(a) Field of the Invention

The present invention relates to an apparatus and method for calculating SOC (State Of Charge) of a secondary battery, and more particularly, to an apparatus and method for calculating SOC of the secondary battery by correcting a terminal voltage.

(b) Description of the Related Art

As the result of international treaties and government mandates, various measures have been taken to reduce greenhouse gases. In particular, restrictions have been imposed on vehicle emissions, which are known to be one of the largest causes of greenhouse gas emissions. As a result, in the automobile industry, the development of an electric vehicle (Electric Vehicle; EV), a hybrid vehicle (Hybrid Electric Vehicle; HEV), a plug-in hybrid vehicle (Plug-in Hybrid Electric Vehicle; PHEV), etc. have been accelerated.

An electric vehicle accumulates electrical energy to a secondary battery, and converts the electrical energy to kinetic energy by using a motor. In general, an electric vehicle is expected to travel long distances (e.g., hundreds of kilometers, or up to a few hundred miles) on a single charge, and the driver has to identify the exact remaining capacity of the battery in order to stably drive suitable distances.

If the measured remaining capacity is inaccurate, driving of the electric vehicle can be stopped, while the driver doesn't notice it. Further, for example, the actual capacity of the battery mounted on a vehicle is 80%, but if the measured capacity is 30%, the battery controller of the vehicle may excessively charge the battery by determining that the battery charging are required, and in the opposite case, the battery may be excessively discharged. This over-charge or over-discharge has the risk of causing fire or explosion.

### SUMMARY

Various embodiments according to the present invention can provide an apparatus and method for calculating State of Charge (SOC) of a battery by measuring the terminal voltage of a battery mounted in a vehicle during driving of the vehicle, performing a predetermined correction, and then calculating SOC of the battery from the corrected voltage.

The apparatus for calculating SOC according to an embodiment of the present invention may comprise a voltage measuring device configured to measure a terminal voltage of a battery a voltage corrector configured to correct the terminal voltage using a predetermined factor obtained from a characteristic of the battery; and a SOC calculator configured to calculate SOC of the battery based on the corrected terminal voltage.

At this time, the predetermined factor may be obtained based on at least an internal resistance value of the battery.

Also, the voltage corrector may correct the terminal voltage so as to follow OCV (Open Circuit Voltage) of the battery.

Also, the SOC calculator may calculate SOC of the battery by applying the corrected voltage to a preset data table.

Also, the apparatus may further comprise a temperature measuring device, and the SOC calculator may calculate SOC of the battery by applying the corrected terminal voltage and a temperature of the battery to the preset data table.

A method for calculating SOC can include steps of: measuring a terminal voltage of a battery; correcting the terminal voltage using a predetermined factor obtained from a characteristic of the battery; and calculating SOC of the battery based on the corrected terminal voltage. An apparatus and method for calculating SOC according to an embodiment of the present invention can calculate SOC with a high accuracy, without directly measuring the current or OCV of a battery, by correcting the terminal voltage using a predetermined factor obtained from the characteristic of the battery and calculating SOC using the factor.

Further, a non-transitory computer readable medium containing program instructions executed by a controller can include: program instructions that measure a terminal voltage of a battery; program instructions that correct the terminal voltage using a predetermined factor obtained from a characteristic of the battery; and program instructions that calculate State of Charge (SOC) of the battery based on the corrected terminal voltage.

### BRIEF DESCRIPTION OF THE DRAWINGS

The above and other objects, features and advantages of the present invention will be more apparent from the following detailed description taken in conjunction with the accompanying drawings, in which:

FIG. 1 is a configuration diagram of an apparatus for calculating SOC according to an embodiment of the present invention.

FIG. 2 is a voltage graph of a battery according to an embodiment of the present invention.

FIG. 3 is a diagram showing a data table according to an embodiment of the present invention.

FIG. 4 is a flow chart showing a method for calculating SOC according to an embodiment of the present invention.

FIG. 5(a)-(e) are time variation graphs of SOC by a method for calculating SOC according to an embodiment of the present invention.

### DETAILED DESCRIPTION OF THE PREFERRED EMBODIMENTS

Although the present invention can be make various modifications and have many embodiments, specific embodiments will be illustrated in the drawing and be described in the detailed description. However, it is not intended to limit the present invention to the specific embodiments, and must be understood as including all modifications, equivalents and substitutes which are included in the spirit and scope of the present invention. If the specific description of the related prior art in the following description of the present invention is determined to obscure the gist of the present invention, a detailed description thereof will be omitted.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Further, the control logic of the present invention may be embodied as non-transitory computer readable media on a computer readable medium containing executable program instructions executed by a processor, controller or the like. Examples of computer readable media include, but are not limited to, ROM, RAM, compact disc (CD)-ROMs, magnetic tapes, floppy disks, flash drives, smart cards and optical data storage devices. The computer readable medium can also be distributed in network coupled computer systems so that the computer readable media is stored and executed in a distributed fashion, e.g., by a telematics server or a Controller Area Network (CAN).

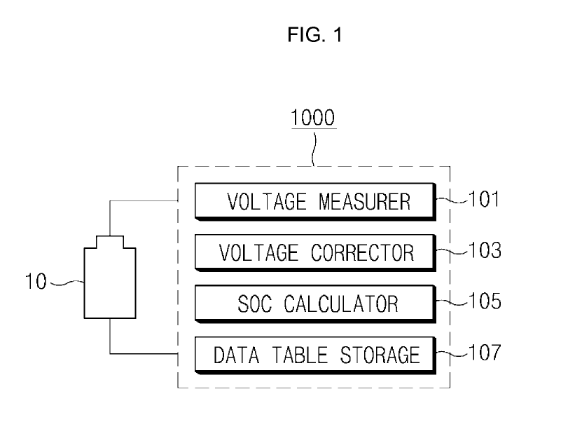

FIG. 1 is a configuration diagram of an apparatus for calculating State of Charge (SOC) according to an embodiment of the present invention.

Referring to FIG. 1, an apparatus 1000 for calculating SOC may include a voltage measuring device 101, a voltage corrector 103, a SOC calculator 105 and a data table storage 107. The apparatus 1000 for calculating SOC may further include a controller, etc. as required in addition to the above components, and for example, may be mounted, and also may be connected with a display, a battery charging device and the like.

A voltage measuring device 101 may measure the terminal voltage of a battery 10.

The voltage corrector 103 may correct the terminal voltage using a predetermined factor obtained from a characteristic of the battery 10. The predetermined factor may be obtained based on at least the internal resistance of the battery 10. The voltage corrector 103 may correct the terminal voltage so as to follow Open Circuit Voltage (OCV) of the battery 10.

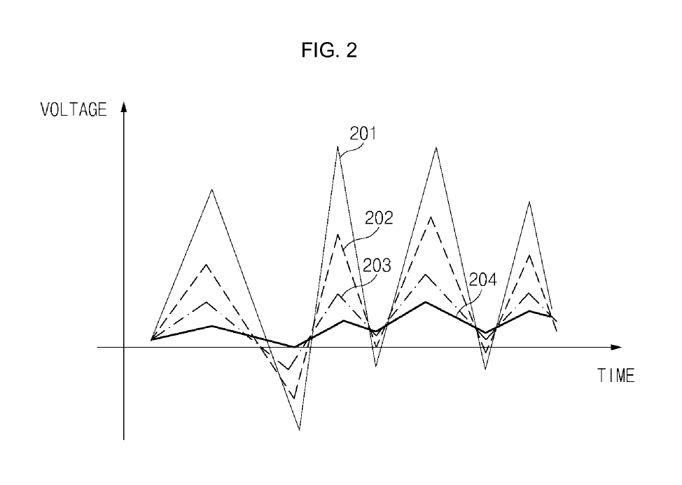

In particular, SOC is not directly calculated from the terminal voltage measured by the voltage measuring device 101. This will be described with reference to FIG. 2.

FIG. 2 is a voltage graph of a battery according to an embodiment of the present invention.

The electric vehicle mounting a battery 10 is driven by a motor generally, and the current value influences the torque value of the motor. Accordingly, accompanying the acceleration/deceleration of the vehicle, the current of the power generated from the battery 10 may be steeply varied moment by moment, and due to the current, the terminal voltage also may be steeply varied (see, for example, the graph 201 of FIG. 2). In particular, the greater the internal resistance of the battery 10 is, the larger the variation of the steep terminal voltage tends to be.

On the other hand, in the case of an electric vehicle and a hybrid vehicle, on decelerating/braking, the generator is operated and the battery 10 may be discharged. Accompanying the charging/discharging, OCV corresponding to the electromotive force of the battery 10 can be raised or lowered (see, for example, the graph 204 of FIG. 2). In particular, OCV can be influenced by the actual charging and discharging, and mainly it is distinguished from the conduction current and the terminal voltage affected by the internal resistance.

However, in order to calculate SOC from OCV by using the following data table, since the battery 10 is necessary to separate from the driving system of the electric vehicle, it is not preferable to efficiently operate the electric vehicle. Accordingly, the voltage corrector 103 according to the present invention can correct the terminal voltage using a predetermined factor obtained from the characteristic of the battery 10 so as to follow OCV, and based on the corrected terminal voltage, SOC can be calculated.

For example, the voltage graphs 202 and 203 of FIG. 2 are graphs which are corrected from the graph 201 using a predetermined factor, respectively. According to the corrected graphs 202 and 203, unlike the graph 201 of the terminal voltage, it can be checked that the variation rate of the voltage is significantly suppressed to be close (following) to the graph 204 of OCV.

At this time, the predetermined factor used to correct the terminal voltage so as to follow OCV can be obtained based on the internal resistance value of the battery 10. In particular, the larger the internal resistance of the battery 10 is, the higher the terminal voltage variation is, and when deriving (tuning) the predetermined factor, it is preferable to consider the internal resistance of the battery 10, a type of the battery 10, a polarization state, etc. On the other hand, since the characteristic of the internal resistance may be different even for the same type of battery 10, it is preferable to use the internal resistance obtained by a test that is repeated. After all, in the case of FIG. 2, it is preferable that the graph 203 close to the graph 204 of OCV, rather than the graph 202, is selected.

The SOC calculator 105 can calculate SOC of the battery 10 based on the corrected terminal voltage. Specifically, the SOC calculator 105 can calculate SOC of the battery 10 by applying the corrected terminal voltage to a preset data table, and also calculate SOC by applying the corrected terminal voltage and the temperature of the battery 10 to the preset data table.

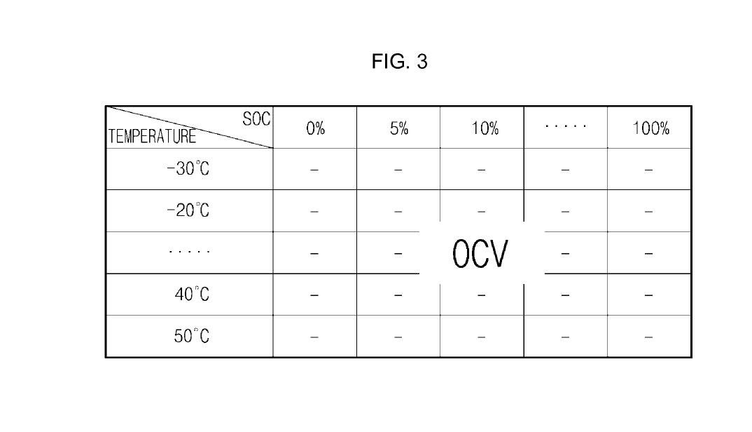

FIG. 3 is a diagram showing a data table according to an embodiment of the present invention.

Referring to FIG. 3, it shows that OCV corresponds to the temperature and SOC value. In the data table of FIG. 3, OCV depending on the temperature and SOC value is depicted, but the type of SOC depending on the temperature and OCV may be also considered, and it may be implemented as a continuous graph, not as a table.

The SOC calculator 105 can calculate SOC of the battery 10 by applying the terminal voltage corrected by the voltage corrector 103 to the preset data table as shown in FIG. 3. In particular, since the SOC calculator 105 measures the actual OCV, and calculates SOC by using the corrected terminal voltage, SOC can be calculated without separating the battery 10 of the electric vehicle from the system.

On the other hand, for the temperature, the apparatus 1000 for calculating SOC may include a temperature measuring device and thus it can be measured, and also it may be obtained from temperature information measured by an external temperature sensor.

The data table storage 107 may store the data table as shown in FIG. 3. The data table storage may be, for example, a hard disk device (HDD), an optical disk device (ODD), a tape device, a flash memory device, or a computer readable medium, and/or have the form of a cloud storage. In addition, it may be periodically or occasionally updated by replacing the battery, or by generation of the change for the internal resistance, etc. according to the aged deterioration.

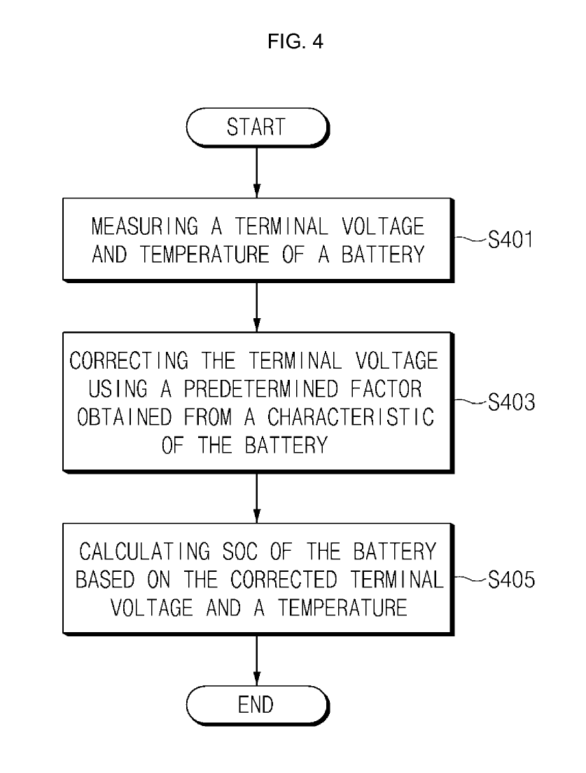

FIG. 4 is a flow chart showing a method for calculating SOC according to an embodiment of the present invention.

Referring to FIG. 4, a method for calculating SOC according to an embodiment of the present invention may include steps of measuring the terminal voltage and temperature of the battery 10 (S401), correcting the terminal voltage using a predetermined factor obtained from the characteristic of the battery 10 (S403), and calculating SOC of the battery 10 based on the corrected terminal voltage (S405).

In step S401, the voltage measuring device 101 may measure the terminal voltage of the battery 10, the temperature measuring device may measure the temperature of the battery 10.

In step S403, the voltage corrector 103 may correct the terminal voltage using a predetermined factor obtained from the characteristic of the battery 10. At this time, the predetermined factor may be obtained based on at least the internal resistance value of the battery, and when performing the correction, it is preferable that the terminal voltage follows OCV of the battery.

In step S405, the SOC calculator 105 may calculate SOC of the battery 10 based on the terminal voltage corrected in step S403. At this time, SOC may be calculated by applying the terminal voltage corrected in step S403 and the temperature measured in step S401 to the data table stored in the data table storage 107.

A method for calculating SOC according to an embodiment of the present invention can calculate SOC with a high accuracy by correcting the terminal voltage using a predetermined factor obtained from the characteristic of the battery 10 and calculating SOC using this, without separating the battery 10 from the system (i.e., without directly measuring OCV). Specifically, the battery 10 is mounted in the electric vehicle, and if the method for calculating SOC is performed during driving of the vehicle, the driver of the electric vehicle can be notified of SOC of the battery 10 in real time.

On the other hand, depending on an embodiment, step S401 to step S405 may be preliminarily performed if the measurement of SOC is impossible by other methods.

In general, as a method for calculating SOC, it is used to obtain SOC by time-integrating the current inputted to and outputted from the battery 10. However, since a high current may flow to the current sensor for measuring the current, the possibility of damage or failure still exists. If the current sensor is damaged or fails, the calculation for SOC of the battery may be difficult.

On the other hand, if a method for calculating SOC according to an embodiment of the present invention is preliminarily performed, even when the current sensor is damaged or fails, it can measure SOC with a high accuracy. By this, there is an advantage which the user can pursue efficient operation when utilizing electric energy accumulated in the battery 100.

Also, the method of the present invention can be implemented as a computer program. In particular, codes and code segments constituting the program can be easily inferred by a computer programmer of ordinary skill in the art. Further, the created program preferably is stored on a non-transitory computer readable recording medium (information storage medium), and can be read and executed by a computer, thereby implementing the method of the present invention. Also, the recording medium includes all type of non-transitory recording media which can read by a computer.

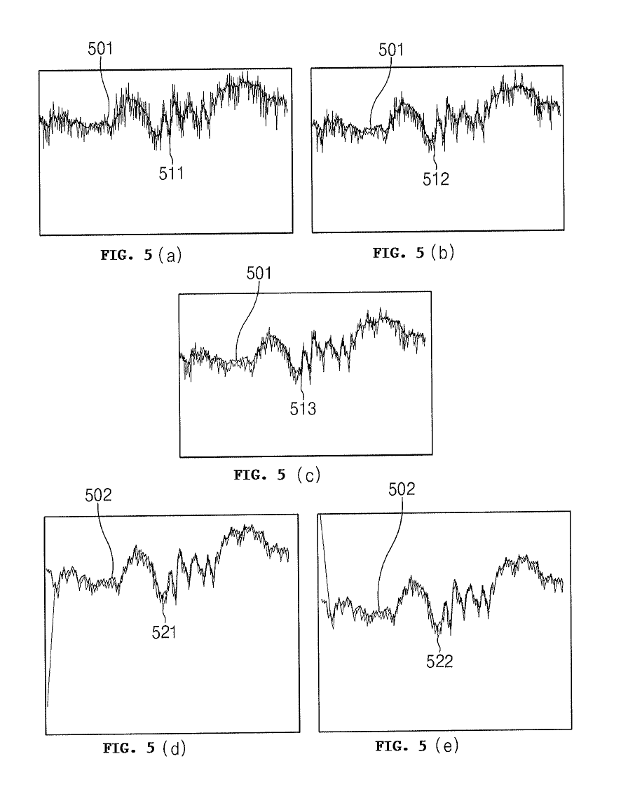

FIG. 5 (a)-(e) are time variation graphs of SOC by a method for calculating SOC according to an embodiment of the present invention.

Referring to FIG. 5 (a)-(e), the horizontal axis is time and the vertical axis represents SOC. The graph 501 is a graph as a reference when comparing with other graphs 511-513 and 521-522, and unlike other graphs 511-513 and 521-5232, it has the shape of a relatively smooth curve. The graph 501 shows the graph which calculates SOC from OCV.

Referring to FIG. 5 (a)-(c), the graphs 511-513 show SOC graphs which are calculated after correcting the terminal voltage of the battery 10 using different predetermined factors, respectively. In FIG. 5 (a), the graph 511 shows that the variation rate of SOC is relatively large. However, by adjusting (tuning) a predetermined factor used to correct the terminal voltage, as shown in the graph 512 of FIG. 5 (b) or desirably, 513 of FIG. 5 (c), the variation rate of SOC can be lowered. Referring to FIG. 5 (c), it can be seen that the graph 513 is almost identical (following) to the graph 501.

In particular, by adjusting (tuning) a predetermined factor used to correct the terminal voltage, it can obtain a predetermined factor most suitable for correcting the terminal voltage. On the other hand, the method is not limited to deriving the most appropriate predetermined factor which is used to correct the terminal voltage by another method as an example.

Referring to FIG. 5 (d)-(e), the graph 521 of FIG. 5 (d) is a SOC graph, which is calculated after correcting the terminal voltage of the battery using a predetermined factor, when the initial SOC is 0%. On the other hand, the graph 522 of FIG. 5 (e) is a SOC graph, which is calculated after correcting the terminal voltage of the battery using the same predetermined factor, when the initial SOC is 100%. It can be seen that the change development of SOC as shown in FIGS. 5 (d) and (e) follows the graph 502 regardless of the initial SOC.

The specific embodiments explained in the present invention correspond to exemplary embodiments, but do not limit the scope of the present invention in any way. In order to simplify the specification, the description for the conventional circuit configurations, control systems, software, other functional aspects of the above systems may be omitted. Further, the connection of lines or the connection members between the components shown in drawings show a functional connection and/or physical or circuit connections as an example, and in the actual device, it may be shown as a replaceable or additional various functional connection, physical connection, or circuit connection. Further, if there is no specific mention such as “essential”, “importantly”, etc., it may be not a component necessary for the application of the present invention.

The use of term “said” and similar terms may correspond to both the singular and the plural in the specification of the present invention (in particular, in the appended claims). Also, if the range is described in the present invention, it includes the invention which the individual value in the range is applied (if there is no opposite description), and it is identical to describe individual value constituting the range. In the present invention, the use of all example or exemplary terms (for example, etc.) is just for explaining the present invention in detail, the scope of the present invention is not limited by the examples or exemplary term, unless the scope of the present invention is limited by the appended claims. In addition, those ordinary skilled in the art can appreciate that various modifications, combinations and changes can be constructed according to the design conditions and factors within the appended claim or their equivalents.

As the above described, since various substitutions, modifications and changes may be made without departing from the technical concept of the present invention those ordinary skilled in the art, the scope of the present invention is not limited by the aforementioned embodiments and accompanying drawings.

What is claimed is:

1. An apparatus for calculating State of Charge (SOC), comprising:
a voltage measuring device configured to measure a terminal voltage of a battery;
a voltage corrector configured to correct the terminal voltage using a predetermined factor obtained from a characteristic of the battery; and
a SOC calculator configured to calculate SOC of the battery based on the corrected terminal voltage.

2. The apparatus for calculating SOC according to claim 1, wherein the predetermined factor is obtained based on at least an internal resistance value of the battery.

3. The apparatus for calculating SOC according to claim 1, wherein the voltage corrector corrects the terminal voltage so as to follow OCV (Open Circuit Voltage) of the battery.

4. The apparatus for calculating SOC according to claim 1, wherein the SOC calculator calculates SOC of the battery by applying the corrected voltage to a preset data table.

5. The apparatus for calculating SOC according to claim 4, wherein the apparatus further comprises a temperature measuring device, and the SOC calculator calculates SOC of the battery by applying the corrected terminal voltage and a temperature of the battery to the preset data table.

6. A method for calculating State of Charge (SOC), comprising:
measuring a terminal voltage of a battery;
correcting the terminal voltage using a predetermined factor obtained from a characteristic of the battery; and
calculating SOC of the battery based on the corrected terminal voltage.

7. The method for calculating SOC according to claim 6, wherein the predetermined factor is obtained based on at least an internal resistance value of the battery.

8. The method for calculating SOC according to claim 6, wherein the step of correcting the terminal voltage includes a step of correcting the terminal voltage so as to follow OCV of the battery.

9. The method for calculating SOC according to claim 6, wherein the step of calculating SOC of the battery includes a step of calculating the SOC of the battery by applying the corrected voltage to a preset data table.

10. The method for calculating SOC according to claim 6, wherein the method further comprises a step of measuring a temperature, and wherein the step of calculating the SOC of the battery includes a step of calculating the SOC of the battery by applying the corrected terminal voltage and the temperature of the battery to the preset data table.

11. The method for calculating SOC according to claim 6, wherein the method is preliminary performed if measurement of SOC is impossible by another method.

12. The method for calculating SOC according to claim 6, wherein the battery is mounted in a vehicle, and the method is performed during driving of the vehicle.

13. A non-transitory computer readable medium containing program instructions executed by a controller, the computer readable medium comprising:
program instructions that measure a terminal voltage of a battery;
program instructions that correct the terminal voltage using a predetermined factor obtained from a characteristic of the battery; and
program instructions that calculate State of Charge (SOC) of the battery based on the corrected terminal voltage.

14. The non-transitory computer readable medium of claim 13, wherein the predetermined factor is obtained based on at least an internal resistance value of the battery.

15. The non-transitory computer readable medium of claim 13, wherein the program instructions that correct the terminal voltage further include correcting the terminal voltage so as to follow OCV of the battery.

16. The non-transitory computer readable medium of claim 13, wherein the program instructions that calculate SOC of the battery include calculating the SOC of the battery by applying the corrected voltage to a preset data table.

17. The non-transitory computer readable medium of claim 13, further comprising program instructions that measure a temperature, and wherein the program instructions that calculate the SOC of the battery include calculating the SOC of the battery by applying the corrected terminal voltage and the temperature of the battery to the preset data table.

18. The non-transitory computer readable medium of claim 13, wherein the program instructions of the computer readable medium are preliminary performed if measurement of SOC is impossible by another method.

19. The non-transitory computer readable medium of claim 13, wherein the battery is mounted in a vehicle, and the program instructions are carried out during driving of the vehicle.
